(19) United States
(12) Patent Application Publication
(10) Pub. No.: US 2026/0371869 A1
(43) Pub. Date: Nov. 19, 2026

(54) FABRICATION METHOD FOR DISPLAY PANEL, DISPLAY PANEL, AND DISPLAY APPARATUS

(71) Applicant: Hefei Visionox Technology Co., Ltd., Hefei (CN)

(72) Inventors: Xingfeng REN, Hefei (CN); Xuejing ZHU, Hefei (CN)

(73) Assignee: Hefei Visionox Technology Co., Ltd., Hefei (CN)

(21) Appl. No.: 19/415,614

(22) Filed: Dec. 10, 2025

(30) Foreign Application Priority Data
May 15, 2025 (CN) 202510629731.0

(51) Int. Cl. H10K 59/131; H10K 59/12; H10K 59/122

(52) U.S. Cl. CPC H10K 59/131; H10K 59/1201; H10K 59/122

(57) ABSTRACT

The present application discloses a fabrication method for a display panel, a display panel, and a display apparatus. The fabrication method includes: forming a plurality of conductive pads on one side of a base substrate, where the conductive pads are located in a bonding area; forming a protective layer on one side of the base substrate, where the protective layer covers the conductive pads; forming an isolation structure on a side of the protective layer facing away from the base substrate, where the isolation structure encloses an isolation opening; fabricating a light-emitting unit and a first encapsulation layer, where at least part of the light-emitting unit is located in the isolation opening, and the first encapsulation layer is disposed on a side of the light-emitting unit facing away from the base substrate; and removing at least part of the protective layer to expose the respective conductive pad.

### CROSS-REFERENCE TO RELATED APPLICATIONS

This application claims priority to Chinese Patent Application No. 202510629731.0, filed on May 15, 2025, which is incorporated herein by reference in its entirety.

### FIELD

The present application relates to the field of display technology, and in particular to a fabrication method for a display panel, a display panel, and a display apparatus.

### BACKGROUND

Organic light-emitting diodes (OLEDs) and flat panel display apparatuses based on technologies such as light-emitting diodes (LEDs) have been widely used in various consumer electronics such as mobile phones, televisions, notebook computers, and desktop computers, and predominate in display apparatuses thanks to their advantages such as high image quality, energy efficiency, slim design, and wide application range.

Relevant contents of the following patents are cited for reference: CN 118251982 A, 202410864269.8, PCT/CN 2024/098407, PCT/CN 2024/102783, PCT/CN 2024/098217, PCT/CN 2024/100935, PCT/CN 2024/102785, PCT/CN 2024/099419, PCT/CN 2024/099072, and CN 116685174 A.

However, the performance of current OLED display products still needs improvement.

### SUMMARY

Embodiments of the present application provide a fabrication method for a display panel, a display panel, and a display apparatus, which are intended to improve the performance of the display panel.

According to an embodiment of the present application which provides a fabrication method for a display panel. The display panel includes an active area and a bonding area. The fabrication method includes:
forming a plurality of conductive pads on one side of a base substrate, where the conductive pads are located in the bonding area; forming a protective layer on one side of the base substrate, where the protective layer covers the conductive pads;
forming an isolation structure on a side of the protective layer facing away from the base substrate, where the isolation structure is located in the active area and encloses an isolation opening;
fabricating a light-emitting unit and a first encapsulation layer, where at least part of the light-emitting unit is located in the isolation opening, and the first encapsulation layer is disposed on a side of the light-emitting unit facing away from the base substrate; and removing at least part of the protective layer to expose at least part of the respective conductive pad.

According to an embodiment of the present application which further provides a display panel. The display panel includes an active area and a bonding area, and the display panel further includes a base substrate, conductive pads, an isolation structure, and a light-emitting unit; the conductive pads are disposed on one side of the base substrate, and the conductive pads are located in the bonding area, and the respective conductive pad includes at least one conductive layer, the conductive layer including a plurality of metal film layers disposed sequentially in a direction away from the base substrate, at least two of the metal film layers being of different materials, and edges of the metal film layers with different materials having a spacing D in a direction parallel to the base substrate, where D satisfies: D ≤ 0.3 μm; the isolation structure is disposed on one side of the base substrate, and the isolation structure is located in the active area and encloses an isolation opening; and at least part of the light-emitting unit is located in the isolation opening.

According to an embodiment of the present application which further provides a display apparatus. The display apparatus includes the display panel described above.

In the fabrication method for a display panel according to the embodiments of the present application, the plurality of conductive pads are formed on one side of the base substrate, where the conductive pads are located in the bonding area; the protective layer is then formed on one side of the base substrate, where the protective layer covers the conductive pad; and after the light-emitting unit and the first encapsulation layer are fabricated, at least part of the protective layer is removed to expose at least part of the respective conductive pad, preventing developing solutions and etching solutions from damaging the conductive pads during the fabrication of the light-emitting unit and the first encapsulation layer, thereby improving the performance of the display panel.

### BRIEF DESCRIPTION OF THE DRAWINGS

In order to describe the embodiments of the present application more clearly, the drawings required for illustration of the embodiments of the present application will be briefly introduced below. Apparently, the drawings as described below are only for part of the embodiments of the present application, and other drawings can also be obtained from these drawings.

FIG. 1 is a schematic flowchart of a fabrication method for a display panel according to an embodiment of the present application;

FIGS. 2-29 are schematic diagrams of a fabrication process of a fabrication method for a display panel according to an embodiment of the present application;

FIG. 30 is a schematic sectional view of a display panel according to an embodiment of the present application;

FIG. 31 is a schematic sectional view of a conductive layer of a display panel according to an embodiment of the present application;

FIG. 32 is a schematic sectional view of another display panel according to an embodiment of the present application; and

FIG. 33 is a schematic sectional view of still another display panel according to an embodiment of the present application.

List of reference signs:
10: Display panel; AA: Active area;
NA: Bonding area; 100: Substrate; 110: Base substrate; 120: Drive circuit layer; 200: Pixel define layer;
210: Pixel defining portion; 211: Step; 220: Pixel opening; 230: Pixel define material layer; 231: Pixel define material portion; 240: Bonding opening;
300: Isolation structure; 300a: Isolation opening; 300aa: First opening; 300ab: Second opening; 300ac: Third opening; 310: First isolation portion; 320: Second isolation portion; 330: Isolation structure material layer;
400: Light-emitting unit; 401: First light-emitting unit; 402: Second light-emitting unit;
403: Third light-emitting unit; 410: First electrode; 420: Second electrode; 430: Light-emitting layer;
510: First encapsulation layer; 511: First encapsulation unit; 512: Second encapsulation unit; 513: Third encapsulation unit; 520: Second encapsulation layer; 530: Third encapsulation layer;
E1: First device material layer; E11: First light-emitting material layer; E12: First conductive material layer;
E2: Second device material layer; E21: Second light-emitting material layer; E22: Second conductive material layer;
E3: Third device material layer; E31: Third light-emitting material layer; E32: Third conductive material layer;
C1: First encapsulation material layer; C2: Second encapsulation material layer; C3: Third encapsulation material layer; P1: First protective layer; P11: First protective material;
P2: Second protective layer; P21: Second protective material;
P3: Third protective layer; P31: Third protective material;
600: Protective layer; 610: Planarization layer; 611: Planarization portion; 612: Planarization material layer; 613: First via; H: Conductive pad; H1: Pad connection line; H2: First conductive layer; H3: Second conductive layer; H4: Third conductive layer; H5: Conductive layer; M: Metal film layer; M1: First metal layer; M2: Second metal layer; M3: Third metal layer; 700: Insulation layer; 710: Second via.

### DETAILED DESCRIPTION OF THE EMBODIMENTS

Features and exemplary embodiments of the present application will be described in detail below. In order to make the embodiments of the present application clearer, the present application will be further described in detail below with reference to the accompanying drawings and specific embodiments. It should be understood that the specific embodiments described herein are merely configured to explain the present application and are not configured to limit the present application. The present application may be implemented without part of these specific details. The following description of the embodiments is merely to provide a better understanding of the present application by illustrating examples of the present application.

It should be noted that, herein, relational terms such as "first" and "second" are only used to distinguish one entity or operation from another entity or operation, and do not necessarily require or imply that such an actual relationship or order exists between these entities or operations. Furthermore, the terms "comprises", "includes" or any other variant thereof are intended to cover non-exclusive inclusion, and a process, method, object or device including a series of elements not only includes those elements, but further includes other elements not explicitly listed, or further includes elements inherent to such process, method, object or device. Without further limitation, an element limited by "comprising/including ..." does not exclude other identical elements existing in the process, the method, the object, or the device that includes the element.

It should be understood that in the description of the structure of a component, a layer or region referred as being located "above" or "over" another layer or region may be directly on the other layer or region, or there may be other layers or regions between the layer or region and the other layer or region. Moreover, when the component is turned over, the layer or region is located "below" or "under" the other layer or region.

In some display panels, due to the presence of an isolation structure, fine metal masks can be eliminated during the evaporation of a light-emitting layer. However, during the fabrication of light-emitting units of different colors, it is necessary to first evaporate a light-emitting unit of a specific color over the entire surface of the display panel, and then etch isolation openings for disposing light-emitting units of other colors in the display panel to remove light-emitting and encapsulation materials from the light-emitting units of other colors. The above operation is then repeated for light-emitting units of different colors to form the light-emitting units of different colors. However, developing solutions and etching solutions in the above steps may easily damage the metal (e.g., aluminum) in conductive pads in a bonding area, causing reliability issues in the conductive pad during the manufacturing process and subsequent use, which affects the performance of the display panel.

The embodiments of the present application provide a display panel 10. The display panel 10 may be an organic light-emitting diode (OLED) display panel 10 or other types of display panels 10, such as a micro light-emitting diode (Micro-LED) display panel 10 or a quantum light-emitting diode (QLED) display panel 10.

The embodiments of the present application provide a fabrication method for a display panel 10 and a display apparatus. The embodiments of the fabrication method for a display panel 10 and the display apparatus will be described below with reference to the accompanying drawings.

As shown in FIG. 1, according to a first aspect, an embodiment of the present application provides a fabrication method for a display panel 10. The display panel 10 includes an active area AA and a bonding area NA. The fabrication method includes the following steps.

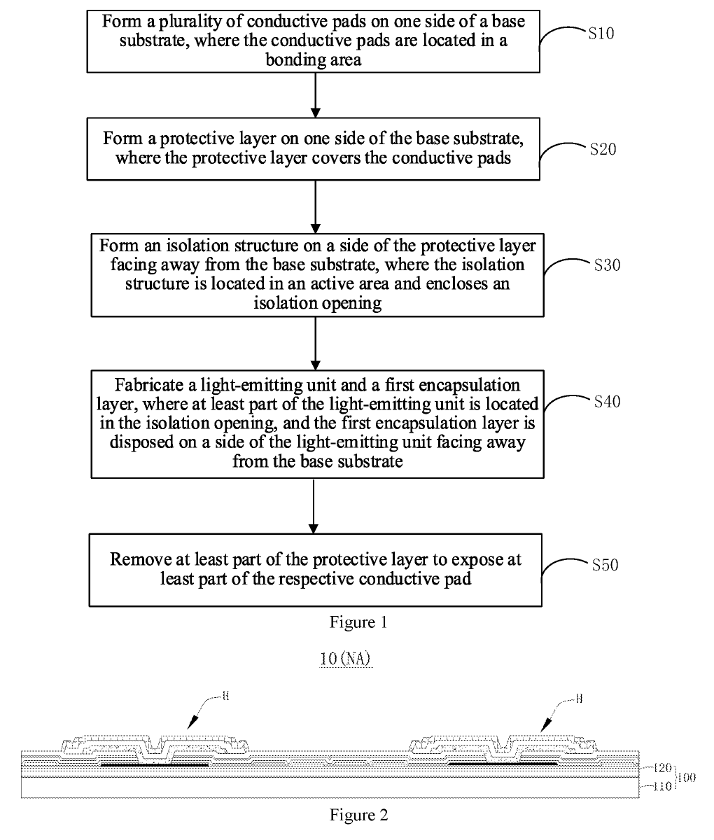

As shown in FIG. 2, at S10, a plurality of conductive pads H are formed on one side of a base substrate 110, where the conductive pads H are located in the bonding area NA.

A substrate 100 of the display panel 10 includes the base substrate 110 and a drive circuit layer 120 disposed on the base substrate 110. The base substrate 110 may be a rigid base substrate 110 made of materials such as glass and plastic, or a flexible base substrate 110 made of materials such as polyethersulfone (PES), polyacrylate (PAR), polyetherimide (PEI), polyethylene naphthalate (PEN), polyethylene terephthalate (PET), polyphenylene sulfide (PPS), polyarylate, polyimide (PI), polycarbonate (PC), or cellulose acetate propionate (CAP). A drive circuit for controlling a light-emitting layer 430 to emit light is disposed in the drive circuit layer 120. The drive circuit layer 120 generally includes inorganic film layers such as a metal layer, a semiconductor layer (active layer), and an insulation layer 700. The drive circuit for controlling the light-emitting layer 430 to emit light may be formed by patterning these inorganic film layers, and there may be various implementations of the specific circuit structure of the drive circuit, which will not be described in detail herein.

The conductive pads H are located at the drive circuit layer 120, and the conductive pads H are configured to bond to a driver chip or a flexible printed circuit board, and the drive circuit can be electrically connected to the driver chip or the flexible printed circuit board, thereby enabling signal transmission.

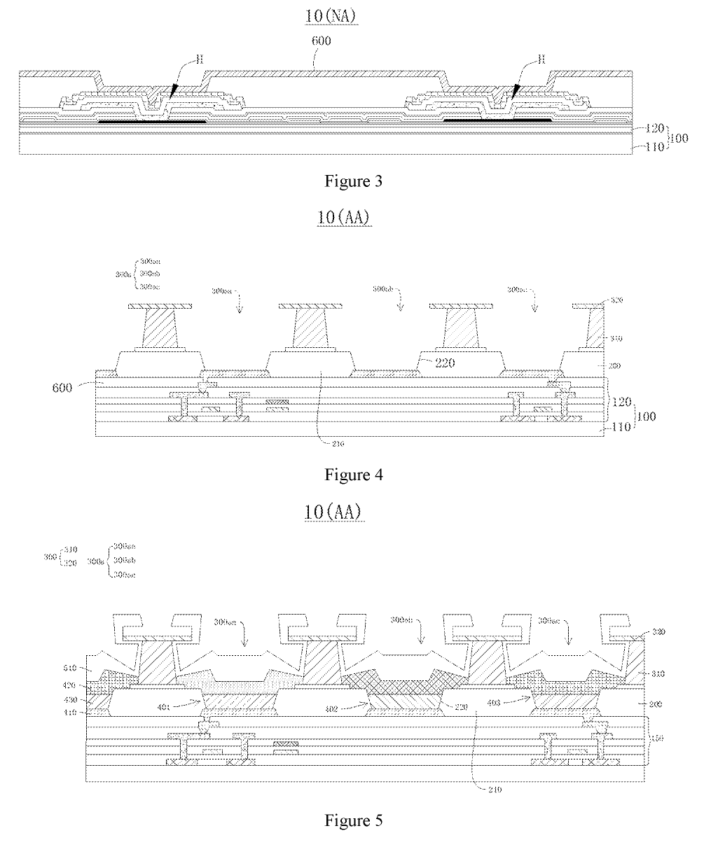

As shown in FIG. 3, at S20, a protective layer 600 is formed on one side of the base substrate 110, where the protective layer 600 covers the conductive pads H.

The protective layer 600 may include a plurality of material layers and cover all of the respective conductive pad H to prevent subsequent processes such as development and etching from damaging the conductive pad H.

As shown in FIG. 4, at S30, an isolation structure 300 is formed on a side of the protective layer 600 facing away from the base substrate 110, where the isolation structure 300 is located in the active area AA and encloses an isolation opening 300a.

It should be noted that in some embodiments, in the top view of the display panel 10, an orthographic projection of the isolation structure 300 on the substrate 100 is annular. The presence of the isolation structure 300 allows light-emitting layers 430 of different light-emitting units 400 to be spaced apart during the fabrication of the display panel 10. Specifically, during the fabrication of the display panel 10, the isolation structure 300 is typically formed first. Then, the light-emitting layer 430 is directly evaporated without the use of a fine metal mask. During this process, due to the presence of the isolation structure 300, part of a light-emitting material is evaporated in the isolation opening 300a, while part of the light-emitting material is evaporated on a side of the isolation structure 300 facing away from the substrate 100. As a result, the light-emitting material on different sides of the isolation structure 300 in a direction parallel to the plane of the substrate 100 is discontinuous, achieving separation of the light-emitting layers 430 of individual light-emitting units 400 without the need for a fine metal mask. Since the evaporation of the light-emitting layer 430 does not require the use of a fine metal mask, the cost is reduced, and the shadow effect caused by the fine metal mask during the evaporation of the light-emitting layer 430 is avoided, allowing for a reduction in the spacing between the light-emitting units 400, thereby improving the brightness of the display surface. Moreover, since an electron transport layer, an electron injection layer, a hole transport layer, a hole injection layer, etc. of the light-emitting layer 430 are all separated by the isolation structure 300, crosstalk between the light-emitting units 400 can be avoided, thereby improving the display effect of the display panel 10.

As shown in FIG. 5, at S40, a light-emitting unit 400 and a first encapsulation layer 510 are fabricated, where at least part of the light-emitting unit 400 is located in the isolation opening 300a, and the first encapsulation layer 510 is disposed on a side of the light-emitting units 400 facing away from the base substrate 110.

The display panel 10 may include a plurality of pixel units spaced apart from each other, each pixel unit including light-emitting units 400 of different colors, for example, a blue light-emitting unit 400, a red light-emitting unit 400, and a green light-emitting unit 400. In addition, each pixel unit may also include four or more light-emitting units 400 formed by the light-emitting units 400 of the above three colors and additional light-emitting units 400 of other colors such as white. Each light-emitting unit 400 includes a first electrode 410, a light-emitting layer 430, and a second electrode 420 stacked sequentially. The first electrode 410 is disposed on the substrate 100. The light-emitting layer 430 further includes a light-emitting material layer, a hole transport layer, an electron transport layer, etc. When the first electrode 410 and the second electrode 420 are powered, electrons and holes migrate from the electron transport layer and the hole transport layer to the light-emitting material layer, respectively, and combine in the light-emitting material layer to form excitons that excite light-emitting molecules, thereby generating visible light for the purpose of display. One of the first electrode 410 and the second electrode 420 may serve as an anode of the light-emitting layer 430, and the other serves as a cathode of the light-emitting layer 430. In the embodiments of the present application, as an example, the first electrode 410 serves as the anode of the light-emitting layer 430, and the second electrode 420 serves as the cathode of the light-emitting layer 430.

The isolation structure 300 includes a first isolation portion 310 and a second isolation portion 320 disposed sequentially in a direction away from the substrate 100, where an orthographic projection of a side of the first isolation portion 310 facing away from the substrate 100 on the substrate 100 is within an orthographic projection of the second isolation portion 320 on the substrate 100.

An edge of the second isolation portion 320 extends outward in a circumferential direction of the first isolation portion 310, and the second electrode 420 is separated by the first isolation portion 310. The first isolation portion 310 has a greater height, and the second isolation portion 320 has a greater width. An orthographic projection of the first isolation portion 310 on the substrate 100 is within the orthographic projection of the second isolation portion 320 on the substrate 100. In this embodiment, by combining the taller first isolation portion 310 with the wider second isolation portion 320, compared to an implementation where the entire isolation structure 300 is configured in an inverted trapezoidal structure, the first isolation portion 310 can isolate the second electrode 420 more effectively. Moreover, the upper second isolation portion 320 provides better reflection and refraction effects, resulting in a more vivid and brighter display effect.

The first electrode 410 is electrically connected to the first isolation portion 310, and adjacent second electrodes 420 can be electrically connected through the first isolation portion 310.

In one embodiment, the first encapsulation layer 510 includes an inorganic material.

The first encapsulation layer 510 may include materials such as silicon oxide, silicon nitride, or silicon oxynitride, which can provide good mechanical support and encapsulation protection to prevent the display panel 10 from being affected by the environment. Moreover, the first encapsulation layer 510 formed by the inorganic material can also effectively present the ingress of harmful substances such as external moisture and oxygen into the interior of the display panel 10, thereby improving the service life and stability of the display panel 10.

At S50, at least part of the protective layer 600 is removed to expose at least part of the respective conductive pad H.

After the light-emitting unit 400 and the first encapsulation layer 510 are fabricated, at least the protective layer 600 is removed to expose areas of the conductive pads H for bonding, for a bonding connection operation.

In the fabrication method for a display panel 10 according to the embodiments of the present application, the plurality of conductive pads H are formed on one side of the base substrate 110, where the conductive pads H are located in the bonding area NA; the protective layer 600 is then formed on one side of the base substrate 110, where the protective layer 600 covers the conductive pads H; and after the light-emitting unit 400 and the first encapsulation layer 510 are fabricated, at least part of the protective layer 600 is removed to expose at least part of the respective conductive pad H, preventing developing solutions and etching solutions from damaging the conductive pads H during the fabrication of the light-emitting unit 400 and the first encapsulation layer 510, thereby improving the performance of the display panel 10.

In some embodiments, the protective layer 600 includes a planarization layer 610 and a pixel define layer 200, and step S20 of forming a protective layer 600 on one side of the base substrate 110 includes the following sub-steps.

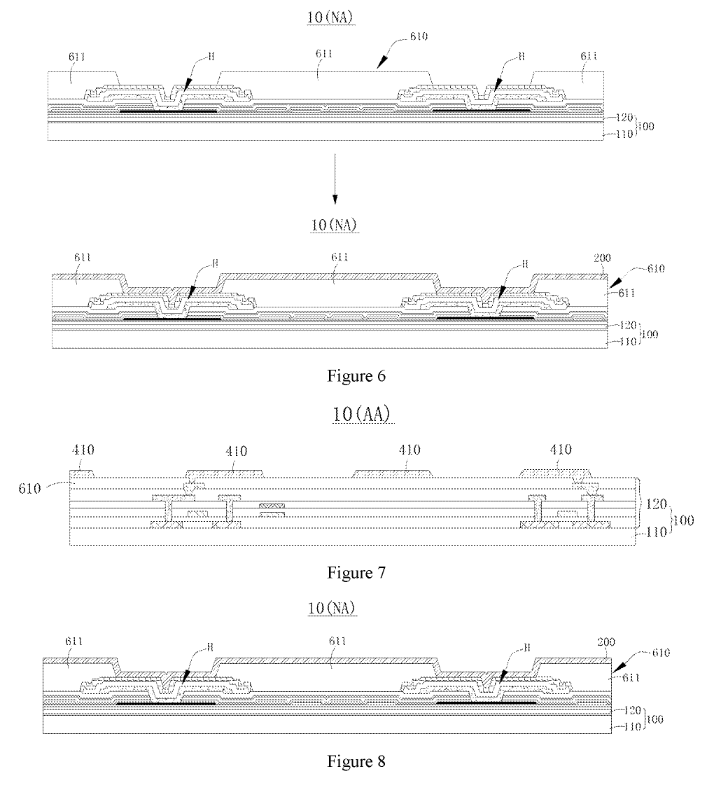

As shown in FIG. 6, at S21, the planarization layer 610 is formed on one side of the base substrate 110, where the planarization layer 610 includes a planarization portion 611 located between two adjacent conductive pads H, and the planarization portion 611 covers edges of the conductive pads H.

The planarization layer 610 may be made of an insulating material. The planarization portion 611 is configured to insulate two adjacent conductive pads H to avoid bridging-induced short circuits.

Covering the edges of the conductive pads H with the planarization portion 611 exposes most of the areas of the conductive pads H for bonding, thereby preventing electrical short circuits between adjacent conductive pads H. When the edges of the conductive pads H are directly exposed and the spacing is small, impurities, moisture, or other factors may cause abnormal current paths. Covering with the planarization portion 611 can effectively prevent this situation, ensuring independent operation of each conductive pad H, thereby ensuring the accuracy and stability of signal transmission. Covering the edges of the conductive pads H with the planarization portion 611 can also enhance the bonding strength between the conductive pads H and the base substrate 110. By covering the edges of the conductive pads H, the risk of peeling, warping, or even detachment at the edges due to external forces, thermal stress, or other factors can be reduced, and the conductive pads H are more securely attached to the base substrate 110 during the fabrication and use of the entire display panel 10, maintaining a good electrical connection.

As shown in FIG. 7, at S22, the first electrode 410 of the light-emitting unit 400 is formed in the active area AA.

The planarization layer 610 is not only located in the bonding area NA, but also covers the active area AA to planarize film layers in the active area AA. Therefore, fabricating the first electrode 410 on the planarization layer 610 ensures a smoother surface of the first electrode 410. This facilitates subsequent uniform deposition of the light-emitting layer 430 and other functional layers, ensuring the performance stability and consistency of the functional layers. Moreover, the smooth first electrode 410 also helps improve the contact performance between the electrode and other layers, reduce contact resistance, and improve electron transfer efficiency, thereby improving the light-emitting effect and overall performance of the display panel 10.

As shown in FIG. 8, at S23, the pixel define layer 200 is formed on a side of the planarization layer 610 facing away from the base substrate 110, where the pixel define layer 200 covers the planarization portion 611 and the conductive pads H.

As shown in FIG. 4, the pixel define layer 200 includes a pixel opening 220, and the isolation opening 300a is in communication with the pixel opening 220.

The isolation opening 300a is disposed in one-to-one correspondence with the pixel opening 220, and an orthographic projection of the pixel opening 220 on the substrate 100 is within an orthographic projection of the isolation opening 300a on the substrate 100. In other words, an isolation unit is provided between every two adjacent light-emitting layers 32 in the display panel 100, to prevent mutual interference between adjacent light-emitting units 400.

In one embodiment, the isolation opening 300a may be disposed correspondingly with at least two pixel openings 220, and orthographic projections of the at least two pixel openings 220 on the substrate 100 are both within the orthographic projection of the corresponding isolation opening 300a on the substrate 100. The isolation opening 300a defined by the isolation structure 20 is disposed correspondingly with the at least two pixel openings 220, i.e., a plurality of spaced light-emitting layers 32 are disposed in the isolation opening 300a, and no isolation structure 20 is disposed between two adjacent light-emitting layers 32 within this portion of the isolation opening 300a. This design allows the density of the isolation structure 20 to be adjusted flexibly based on application requirements. The size of the isolation opening 300a defined by the isolation structure 20 is greater than that of the pixel opening 220. This design prevents the isolation structure 20 from blocking the light emitted by the light-emitting layer 32 in the pixel opening 220.

The pixel define layer 200 not only covers the active area AA, but also extends to the bonding area NA, covering the planarization portion 611 and the conductive pads H, thereby protecting the conductive pads H from erosion by developing solutions and etching solutions in subsequent fabrication processes.

In some embodiments, step S21 of forming a planarization layer 610 on one side of the base substrate 110 includes the following sub-steps.

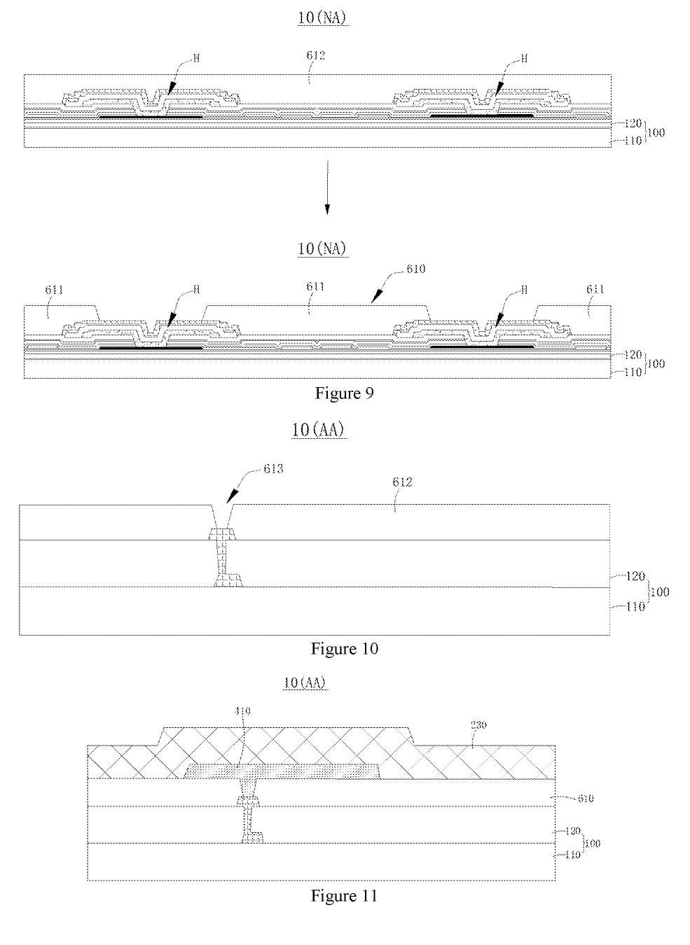

As shown in FIG. 9, at S211, a planarization material layer 612 is formed on one side of the base substrate 110.

A layer of planarization material may be deposited uniformly on the base substrate 110. This planarization material may be an insulating material, such as a commonly used organic insulating material (e.g., polyimide), and the deposition method may involve physical vapor deposition (PVD) or coating processes (e.g., spin coating).

Due to potential height differences and lack of surface smoothness in the previously formed conductive pads H and drive circuit layer 120, the uniformity and quality of subsequent functional layers may be affected. The planarization material layer 612 provides a relatively smooth base surface for subsequent process steps. Additionally, the planarization material layer 612 serves as an insulation layer 700, which can initially isolate different conductive structures in the conductive pads H and the drive circuit layer 120, preventing electrical faults such as short circuits due to accidental contact during subsequent processes.

At S212, a portion of the planarization material layer 612 that corresponds to the bonding area NA is patterned to expose a portion of the conductive pads H to form the planarization portion 611.

In the bonding area NA, the already formed planarization material layer 612 is processed by using photolithography and etching processes. First, the planarization material layer 612 is coated with a photoresist by using the photolithography process, and then the pattern of areas to be retained and removed is transferred onto the photoresist through exposure by using a mask. After development, a pattern consistent with the design pattern is formed on the photoresist. Then a portion of the planarization material layer 612 uncoated with the photoresist is removed by using the etching process, to expose the portion of the conductive pads H. The remaining portion of the planarization material layer 612 forms the planarization portion 611.

The planarization portion 611 covers the edge of the conductive pads H, enabling electrical isolation between adjacent conductive pads H, avoiding potential short circuits due to a small spacing between the edges of the conductive pads H, and ensuring independent signal transmission by each conductive pad H. In addition, the planarization portion 611 protects the edge of the conductive pads H from damage caused by external forces, chemical reagents, or other factors in subsequent processes, and also makes the surface of the bonding area NA more uniform, facilitating uniform coverage of subsequent functional layers, such as the protective layer 600.

As shown in FIG. 10, at S213, a first via 613 is formed in a portion of the planarization material layer 612 that corresponds to the active area AA, where the first via 613 is configured to connect the light-emitting unit 400 to a drive circuit.

The second electrode 420 may be fabricated directly on the planarization material layer 612, with a portion of the second electrode 420 being filled in the first via 613. On the planarization material layer 612 in the active area AA, some small holes penetrating the planarization material layer 612, i.e., the first vias 613, are formed by using photolithography, etching, and other processes. The positions of these vias are designed based on requirements for the electrical connection between the light-emitting unit 400 and the drive circuit. Similarly, the planarization material layer 612 may be first coated with a photoresist, exposure and development may be performed by using a mask, to form a via pattern, and then the planarization material beneath the areas coated with the photoresist may be etched away, thereby forming the first via 613.

The first via 613 may be configured to connect the first electrode 410 of the light-emitting unit 400 to a power supply line of the drive circuit layer 120. The presence of the first via 613 builds an electrical connection bridge between the light-emitting unit 400 and the drive circuit. The drive circuit transmits control signals and current to the light-emitting unit 400 through the first via 613, enabling precise control over the light-emitting state of the light-emitting unit 400. This allows the functional layers in the active area AA to work together, ensuring normal display of images and other information on the display panel 10. Moreover, the formation of the first via 613 is based on the planarization material layer 612, which utilizes insulating properties of the planarization material layer 612 to isolate other circuit parts that do not need to be connected, and achieves specific electrical connections through the vias. This optimizes the circuit structure layout of the active area AA.

In some embodiments, step S23 of forming a pixel define layer 200 on a side of the planarization layer 610 facing away from the base substrate 110 includes the following sub-steps.

As shown in FIG. 11, at S231, a pixel define material layer 230 is formed on the side of the planarization layer 610 facing away from the base substrate 110.

A continuous pixel define material layer 230 is fabricated over the entire surface of the planarization layer 610.

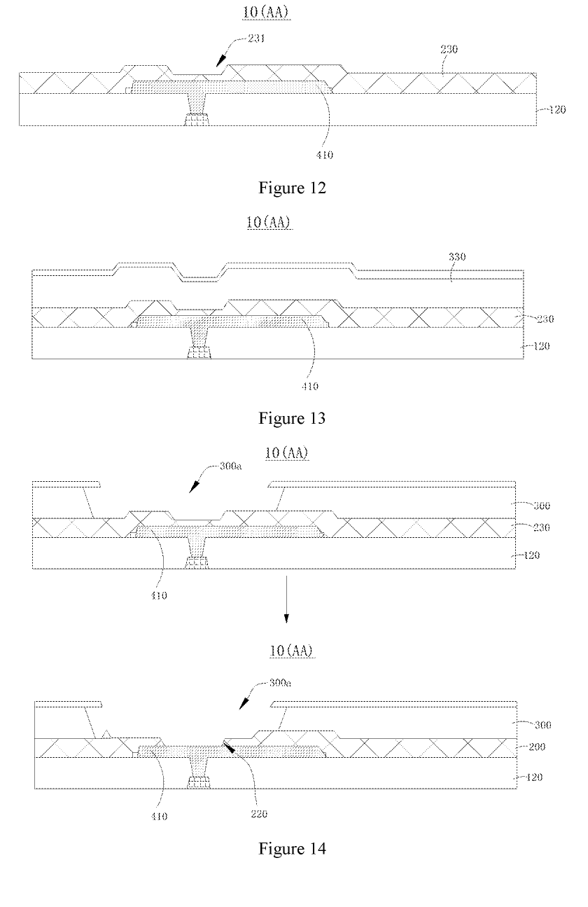

As shown in FIG. 12, at S232, a portion of material of the pixel define material layer 230 that corresponds to the first electrode 410 is etched away, to form a pixel define material portion 231.

The portion of material of the pixel define material layer 230 that corresponds to the first electrode 410 may be removed by using photolithography and etching processes. First, the pixel define material layer 230 is coated with a photoresist by using the photolithography process, and then exposure and development are performed by using a mask, and the photoresist forms a pattern corresponding to the position of the first electrode 410. Next, the pixel define material uncoated with the photoresist is removed by using the etching process. The remaining pixel define material forms the pixel define material portion 231. In other words, only a portion of the pixel define material layer 230 above the first electrode 410 is removed, with another portion being retained. The thickness of the pixel define material layer 230 above the first electrode 410 is thinner compared to that of the pixel define material layer 230 in other areas.

This step creates space above the first electrode 410 for the deposition and formation of subsequent functional layers such as the light-emitting layer 430. Moreover, the pixel define material layer 230 above the first electrode 410 is not completely removed, with the part of the pixel define material portion 231 being retained. In this way, the first electrode 410 can be protected from damage caused by over-etching in subsequent processes. For example, during the etching process for the subsequent fabrication of the isolation structure 300, over-etching may occur and damage the first electrode 410. The embodiments of the present application can prevent this phenomenon from happening.

As shown in FIG. 13, at S233, an isolation structure material layer 330 is fabricated.

A continuous isolation structure material layer 330 is fabricated over the entire surface.

As shown in FIG. 14, at S234, the isolation structure material layer 330 is patterned to form the isolation structure 300 with the isolation opening 300a, and the pixel define material portion 231 is removed to form the pixel define layer 200 with the pixel opening 220.

The isolation structure material layer 330 may further be processed by using photolithography and etching processes. First, the isolation structure material layer 330 is coated with a photoresist, and then exposure and development are performed by using a mask, and the photoresist forms a pattern corresponding to the isolation opening 300a and the pixel opening 220. Then, the isolation structure material and the pixel define material portion 231 uncoated with the photoresist are removed by using the etching process, forming the isolation structure 300 with the isolation opening 300a and the pixel define layer 200 with the pixel opening 220.

The first electrode 410 may be exposed through the pixel opening 220, the pixel opening 220 may be in communication with the isolation opening 300a, and the pixel define layer 200 may be configured to divide sub-pixels of the display panel 10. In one embodiment, the pixel opening 220 being in communication with the isolation opening 300a may refer to a single pixel opening 220 being in communication with a single isolation opening 300a.

This step ultimately results in the isolation structure 300 with the isolation opening 300a and the pixel define layer 200 with the pixel opening 220. The isolation opening 300a is configured to define the position and shape of the light-emitting unit 400, ensuring mutual isolation between different light-emitting units 400 and reducing optical crosstalk and electrical interference. The pixel opening 220 provides precise control over the position and size for the deposition of the light-emitting layer 430, ensuring that each pixel can emit light independently, thereby achieving a high-quality display effect.

When the isolation opening 300a and the pixel opening 220 are formed by etching after the pixel define material layer 230 and the isolation structure material layer 330 are sequentially fabricated, the process of forming the pixel opening 220 in a single step requires etching away a thick portion of material from the pixel define material layer 230. This increases the etching time, resulting in a larger slope of an inclination angle of the pixel defining portion 210 toward the pixel opening 220. As a result, the second electrode 420 has difficulty in climbing the slope and is prone to fracture, which may result in poor bridging between the second electrode 420 and the isolation structure 300, preventing proper connection between adjacent second electrodes 420, and reducing the reliability of the display panel 10. In contrast, in the embodiments of the present application, the portion of material of the pixel define material layer 230 that corresponds to the first electrode 410 is first etched away, to form the pixel define material portion 231, then the isolation structure material layer 330 is patterned to form the isolation structure 300 with the isolation opening 300a, and the pixel define material portion 231 is removed to form the pixel define layer 200 with the pixel opening 220. This reduces the time required for etching the pixel define material layer 230 in a single step, resulting in a moderate slope of the inclination angle of the pixel defining portion 210 toward the pixel opening 220. Therefore, the second electrode 420 can smoothly and continuously climb to the top surface of the pixel defining portion 210, ensuring the bridging between the second electrode 420 and the isolation structure 300, thereby achieving an electrical connection between adjacent second electrodes 420, and improving the reliability of the display panel 10.

In some embodiments, the planarization layer 610 includes an organic material, and the pixel define layer 200 includes an inorganic material.

Organic materials have good fluidity and processability. During processes such as spin coating, the organic materials can effectively fill minor undulations and gaps on the surface of the base substrate 110, especially excelling in covering the edges of the conductive pads H and planarizing the film layers in the active area AA. For example, common organic planarization materials such as polyimide can spread uniformly on the base substrate 110 during high-speed spin coating, forming a thin film with uniform thickness and high surface flatness. This provides an ideal base plane for the subsequent fabrication of various functional layers, helping improve the uniformity and quality of functional layers to be deposited subsequently (e.g., the first electrode 410 and the isolation structure material layer 330).

Inorganic materials (e.g., silicon oxide and silicon nitride) have high chemical stability and can effectively resist erosion by chemical reagents, such as developing solutions and etching solutions, in subsequent fabrication processes. During the fabrication of the display panel 10,a plurality of photolithography, etching, and other processes are required. The use of an inorganic material for the pixel define layer 200 ensures that the pixel define layer will not be excessively corroded or damaged during these processes, thereby precisely maintaining the shape and dimensional precision of the pixel opening 220 and the overall structure thereof. This ensures performance consistency and stability of each pixel unit, improving the yield rate of the display panel 10.

During the manufacturing and use of electronic devices such as the display panel 10, gases may be released from materials, and such a phenomenon is known as "out gas". For example, under specific conditions such as vacuum or high temperatures, some volatile components in materials may volatilize and form gases. The use of an inorganic material for the pixel define layer 200 prevents "out gas" because inorganic materials generally have lower volatility and higher thermal stability, and are less likely to release gases during the manufacturing process or use compared to some organic materials.

In some embodiments, step S50 of removing at least part of the protective layer 600 includes the following sub-steps.

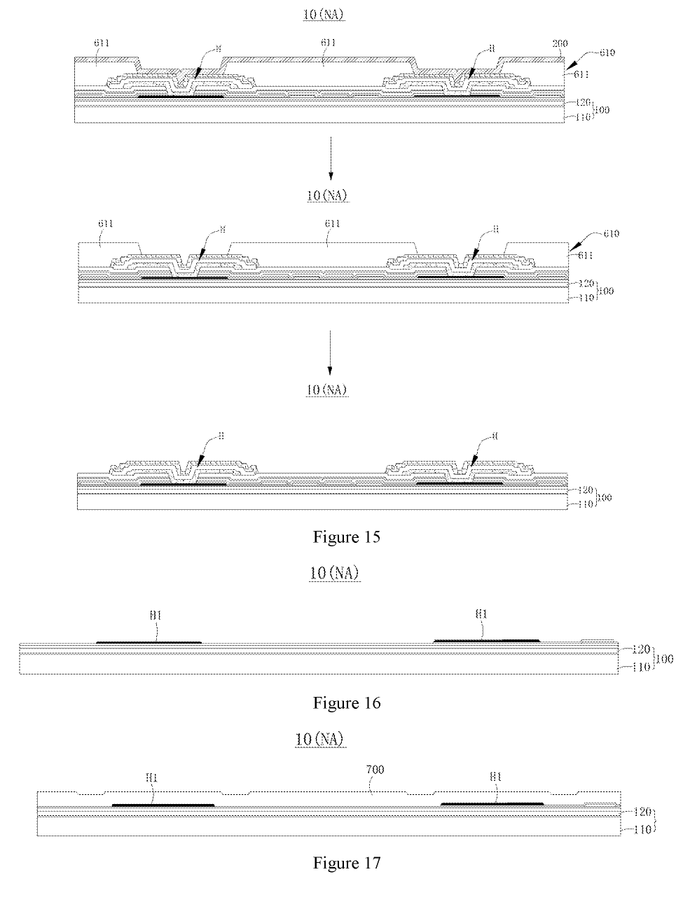

As shown in FIG. 15, at S51. a portion of the pixel define layer 200 that covers the bonding area NA is removed.

The portion of material of the pixel define layer 200 that covers the bonding area NA may be removed by using a specific process, e.g., a dry etching (DE) process. The dry etching process utilizes technologies such as plasma to precisely remove the material from specific areas without the use of liquid chemical reagents. By precisely removing the portion of the pixel define layer 200 in the bonding area NA, clear space is provided for subsequent bonding of the conductive pads H with the driver chip, thereby preventing the pixel define layer 200 from hindering the bonding process, and ensuring a good connection between the driver chip and the conductive pads H. Moreover, the dry etching process has high precision and controllability, which ensures that the removal process does not damage the pixel define layer 200 in other areas.

At S52, a portion of the planarization layer 610 that covers the bonding area NA is removed to expose the conductive pads H, where the conductive pads H are configured to bond to the driver chip.

The portion of the planarization layer 610 that covers the bonding area NA may be removed by using an oxygen plasma ashing (O₂ ashing) process, to fully expose the conductive pads H. The oxygen plasma ashing process utilizes a chemical reaction between the oxygen plasma and the material of the planarization layer 610 to convert the material into volatile products for removal.

This effectively removes the portion of the planarization layer 610 in the bonding area NA, allowing the conductive pads H to be fully exposed for bonding to the driver chip. The oxygen plasma ashing process has advantages such as high selectivity for removing organic materials and little damage to the base substrate 110 and other functional layers, to remove the planarization layer 610 without affecting other structures, thereby providing a good foundation for a subsequent bonding process and ensuring the bonding reliability and stability.

Since in the embodiments of the present application, the conductive pads H are configured to bond to the driver chip and the driver chip tends to generate heat, higher reliability is required for bonding to the driver chip. Organic materials are susceptible to high temperatures. Therefore, in the embodiments of the present application, the portion of the planarization layer 610 that covers the bonding area NA is completely removed, that is, the organic material that may affect the bonding area NA is removed, thereby improving the reliability of the bonding area NA.

Certainly, to remove the portion of the planarization layer 610 that covers the bonding area NA, the portion of the pixel define layer 200 that covers the bonding area NA needs to be removed first. Therefore, in the embodiments of the present application, after the portion of the pixel define layer 200 that covers the bonding area NA is removed, the portion of the planarization layer 610 that covers the bonding area NA is removed to fully expose the conductive pads H for bonding to the driver chip, thereby improving the reliability of the bonding area NA.

In some embodiments, step S10 of forming a plurality of conductive pads H on one side of the base substrate 110 includes the following sub-steps.

As shown in FIG. 16, at S11, pad connection lines H1 are formed on one side of the base substrate 110.

Metal connection lines for connecting the conductive pads H to other circuit elements are formed on the base substrate 110. The connection lines provide paths for subsequent transmission of electrical signals by the conductive pads H.

As shown in FIG. 17, at S12, an insulation layer 700 is fabricated.

A layer of insulating material is fabricated on the surface of the base substrate 110 where the pad connection lines H1 have been formed, to electrically isolate the pad connection lines H1 from other structures to be formed subsequently, preventing short circuits or other issues.

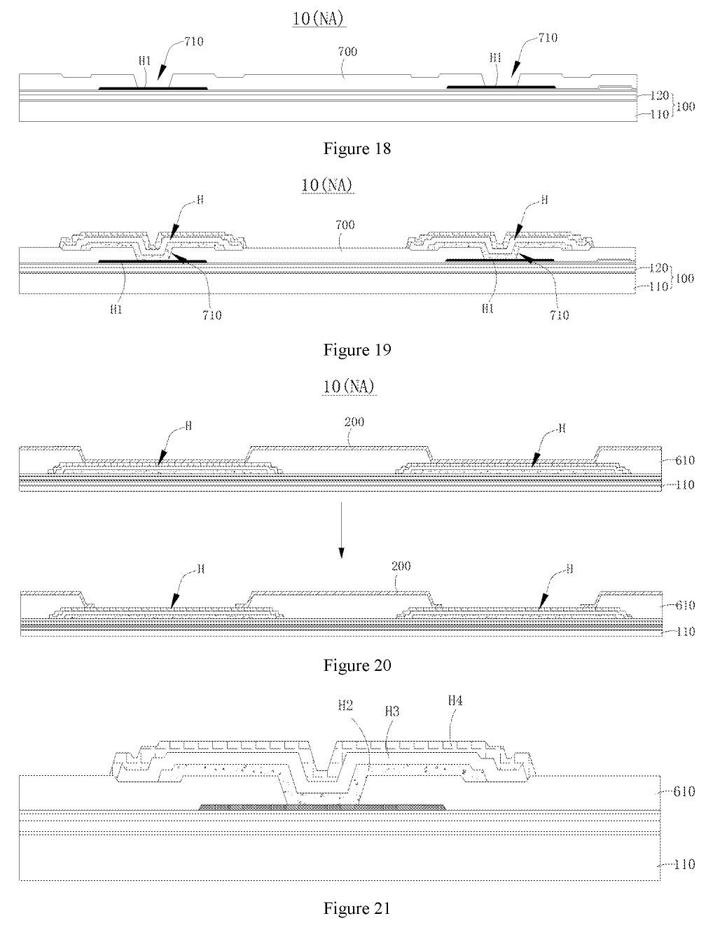

As shown in FIG. 18, at S13, second vias 710 are formed at positions of the insulation layer 700 that correspond to the pad connection lines.

By forming the second vias 710 in the insulation layer 700 at the positions corresponding to the pad connection lines H1, the conductive pads H to be subsequently formed can be electrically connected to the pad connection lines H1 through these second vias 710.

As shown in FIG. 19, at S14, the conductive pads H are formed at positions of the second vias 710, where a portion of the respective conductive pad H is located within the second via 710, and another portion of the respective conductive pad H is located on a side of the insulation layer 700 facing away from the base substrate 110.

The conductive pads H may be formed by using metal deposition and photolithography processes. Conductive structures for bonding to an external driver chip or other elements, i.e., the conductive pads H, are formed at the positions of the previously formed second vias 710 and the side of the insulation layer 700 facing away from the base substrate 110. The conductive pads H may be deposited on the bottom and inner sidewalls of the second vias 710, to ensure a stable electrical connection with external elements during bonding, thereby achieving normal driving and display functions of the display panel 10.

As shown in FIG. 20, in some embodiments, step S50 of removing at least part of the protective layer includes the following sub-step.

At S51, at least part of the pixel define layer 200 that covers the conductive pads H is removed, where the conductive pads H are configured to bond to a flexible printed circuit board.

Since the flexible printed circuit board generates less heat compared to the driver chip, the flexible printed circuit board does not require as high bonding reliability as the driver chip. In the embodiments of the present application, only at least part of the pixel define layer 200 that covers the conductive pads H is removed, with part of the pixel define layer 200 and the entire planarization layer 610 being retained, which can reduce process steps, thereby improving the fabrication efficiency of the display panel 10.

As shown in FIG. 21, in some embodiments, the respective conductive pad H includes a first conductive layer H2, a second conductive layer H3, and a third conductive layer H4 disposed sequentially in a direction away from the base substrate 110.

The first conductive layer H2, the second conductive layer H3, and the third conductive layer H4 may all be fabricated by using a plurality of metal film layers M, for example, three metal film layers M including titanium, aluminum, and titanium. Different conductive layers may be made of different materials with good conductivity. In the embodiments of the present application, the multi-layer structure by stacking the first conductive layer H2, the second conductive layer H3, and the third conductive layer H4 can reduce resistance, minimize signal loss during transmission, and ensure efficient and stable transmission of electrical signals between the conductive pads H and external elements, thereby improving the overall performance of the display panel 10.

In some embodiments, an orthographic projection of the first conductive layer H2 on the base substrate 110 is within an orthographic projection of the second conductive layer H3 on the base substrate 110.

An edge of the second conductive layer H3 extends beyond an edge of the first conductive layer H2, and the second conductive layer H3 has a larger contact area with an upper structure to be connected subsequently (e.g., a pin of the driver chip, or the flexible printed circuit board). The larger contact area can reduce contact resistance, and minimize signal transmission loss and heat generation caused by poor contact, thereby improving the stability and reliability of the electrical connection between the conductive pads H and external elements. For example, when the driver chip is bonded with the conductive pads H, the larger area of the second conductive layer H3 can better accommodate a solder material, making the soldering more secure, thereby ensuring that signals can be stably transmitted from the driver chip to the conductive pads H and the entire circuit of the display panel 10.

In one embodiment, the orthographic projection of the second conductive layer H3 on the base substrate 110 is within an orthographic projection of the third conductive layer H4 on the base substrate 110. An edge of the third conductive layer H4 extends beyond the edge of the second conductive layer H3, and the larger coverage of the third conductive layer H4 can significantly increase the contact area between the conductive pads H and connection elements such as a pin of the external driver chip. The increased contact area can effectively reduce contact resistance and reduce energy loss during signal transmission, thereby ensuring more efficient and stable transmission of electrical signals from external elements to the conductive pads H, and further into the internal circuit of the display panel 10, and improving the overall performance and stability of the display panel 10.

In some embodiments, the isolation opening 300a includes a first opening 300aa and a second opening 300ab, and the step of fabricating a light-emitting unit 400 and a first encapsulation layer 510 includes the following sub-steps.

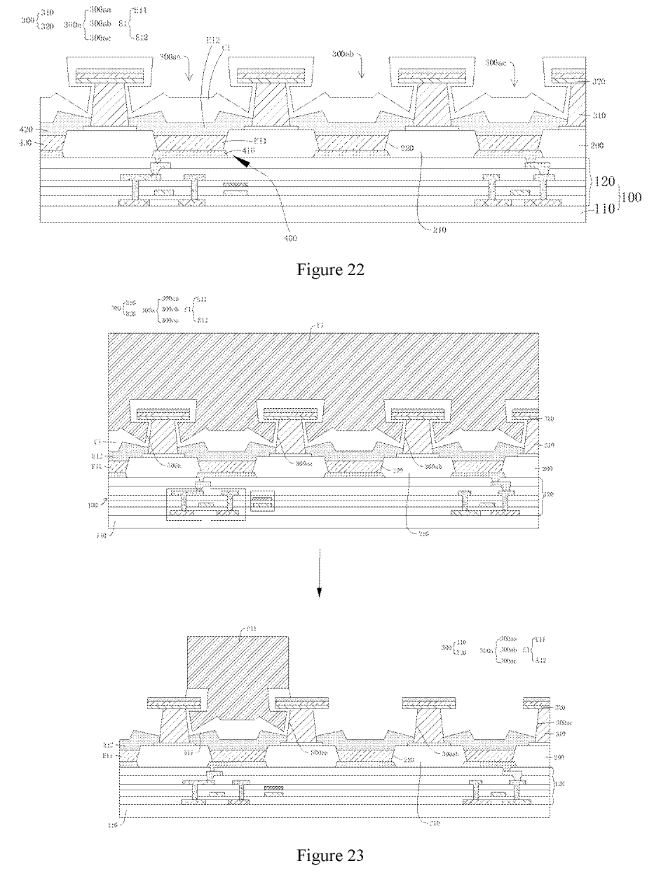

As shown in FIG. 22, at S41, a first light-emitting material layer E11, a first conductive material layer E12, and a first encapsulation material layer C1 are sequentially fabricated over the entire surface.

A first device material layer E1 may include the first light-emitting material layer E11 and the first conductive material layer E12 located on a side of the first light-emitting material layer E11 facing away from the substrate 100.

In one embodiment, the first device material layer E1 may be fabricated by using an evaporation process. In one embodiment, the first encapsulation material layer C1 may be fabricated by using a chemical vapor deposition (CVD) process.

In one embodiment, fabricating the first device material layer E1 and the first encapsulation material layer C1 over the entire surface may refer to that the first device material layer E1 and the first encapsulation material layer C1 may be located within the first opening 300aa, the second opening 300ab, and a third opening 300ac, and that the first device material layer E1 and the first encapsulation material layer C1 may also be located on the side of the isolation structure 300 facing away from the substrate 100.

In one embodiment, due to the blocking and separation effect of the isolation structure 300, a portion of the first device material layer E1 located within the first opening 300aa may be isolated from the other portion of the first device material layer E1 outside the first opening 300aa, a portion of the first device material layer E1 located within the second opening 300ab may be isolated from the other portion of the first device material layer E1 outside the second opening 300ab, and a portion of the first device material layer E1 located within the third opening 300ac may be isolated from the other portion of the first device material layer E1 outside the third opening 300ac. In one embodiment, due to the blocking and separation effect of the isolation structure 300, the first device material layer E1 cannot cover an inner wall of the isolation opening 300a in a large area and with good continuity.

In one embodiment, the first encapsulation material layer C1 may not be affected by the blocking and separation effect of the isolation structure 300, i.e., the first encapsulation material layer C1 may exhibit good continuity.

As shown in FIG. 23, at S42, at least part of the first encapsulation material layer C1 outside the first opening 300aa is removed to form a first encapsulation unit 511 disposed corresponding to the first opening 300aa.

A first protective layer P1 is fabricated on the first encapsulation material layer C1, and the first protective layer P1 is patterned to form a first protective material P11 disposed corresponding to the first opening 300aa.

In one embodiment, the first protective layer P1 may include a photoresist. In one embodiment, patterning the first protective layer P1 may specifically refer to patterning the first protective layer P1 outside the first opening 300aa by using exposure and development processes, followed by removing the at least part of the first encapsulation material layer C1 outside the first opening 300aa, to form the first encapsulation unit 511 disposed corresponding to the first opening 300aa.

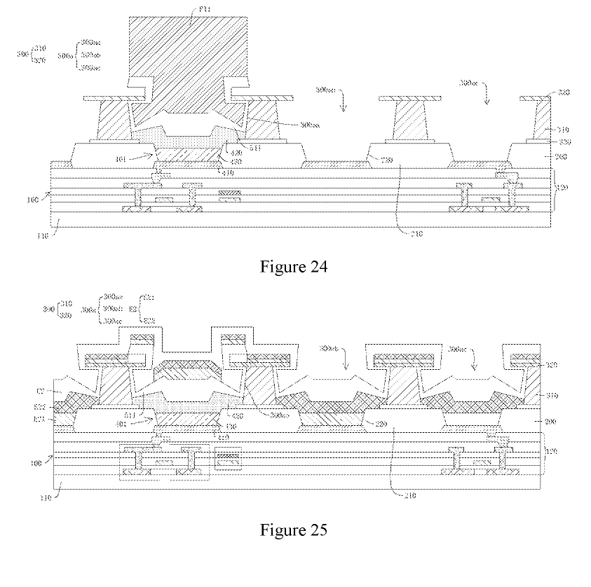

As shown in FIG. 24, at S43, the first conductive material layer E12 and the first light-emitting material layer E11 outside the first opening 300aa are removed to form a first light-emitting unit 401 disposed corresponding to the first opening 300aa.

In one embodiment, the first light-emitting unit 401 may include a first electrode 410, a light-emitting layer 430, and a second electrode 420 disposed corresponding to the first opening 300aa. The second electrode 420 may be located on a side of the first electrode 410 facing away from the substrate 100, and the light-emitting layer 430 may be located between the first electrode 410 and the second electrode 420.

In one embodiment, the first electrode 410 disposed corresponding to the first opening 300aa in the first light-emitting unit 401 may refer to a first electrode 410 located within a pixel opening 220 in communication with the first opening 300aa. In one embodiment, a portion of the structure of the light-emitting layer 430 in the first light-emitting unit 401 may be located within the first opening 300aa, and another portion of the structure of the light-emitting layer 430 in the first light-emitting unit 401 may be located within the pixel opening 220 in communication with the first opening 300aa. In one embodiment, a portion of the structure of the second electrode 420 in the first light-emitting unit 401 may be located within the first opening 300aa, and another portion of the structure of the second electrode 420 in the first light-emitting unit 401 may be located within the pixel opening 220 in communication with the first opening 300aa.

As shown in FIG. 25, at S44, a second light-emitting material layer E21, a second conductive material layer E22, and a second encapsulation material layer C2 are sequentially fabricated over the entire surface.

A second device material layer E2 includes the second light-emitting material layer E21 and the second conductive material layer E22. The second device material layer E2 may be fabricated by using an evaporation process, and the second encapsulation material layer C2 may be fabricated by using a chemical vapor deposition process.

In one embodiment, fabricating the second device material layer E2 and the second encapsulation material layer C2 over the entire surface may refer to that the second device material layer E2 and the second encapsulation material layer C2 may be located above the first encapsulation unit 511, within the second opening 300ab, and within the third opening 300ac, and that the second device material layer E2 and the second encapsulation material layer C2 may be further located on the side of the isolation structure 300 facing away from the substrate 100.

In one embodiment, the second device material layer E2 may include the second light-emitting material layer E21 and the second conductive material layer E22 located on a side of the second light-emitting material layer E21 facing away from the substrate 100.

In one embodiment, due to the blocking and separation effect of the isolation structure 300, a portion of the second device material layer E2 located within the second opening 300ab may be isolated from the other portion of the second device material layer E2 outside the second opening 300ab, and a portion of the second device material layer E2 located within the third opening 300ac may be isolated from the other portion of the second device material layer E2 outside the third opening 300ac. In one embodiment, due to the blocking and separation effect of the isolation structure 300, the second device material layer E2 cannot cover an inner wall of the isolation opening 300a in a large area and with good continuity.

In one embodiment, the second encapsulation material layer C2 may not be affected by the blocking and separation effect of the isolation structure 300, i.e., the second encapsulation material layer C2 may exhibit good continuity.

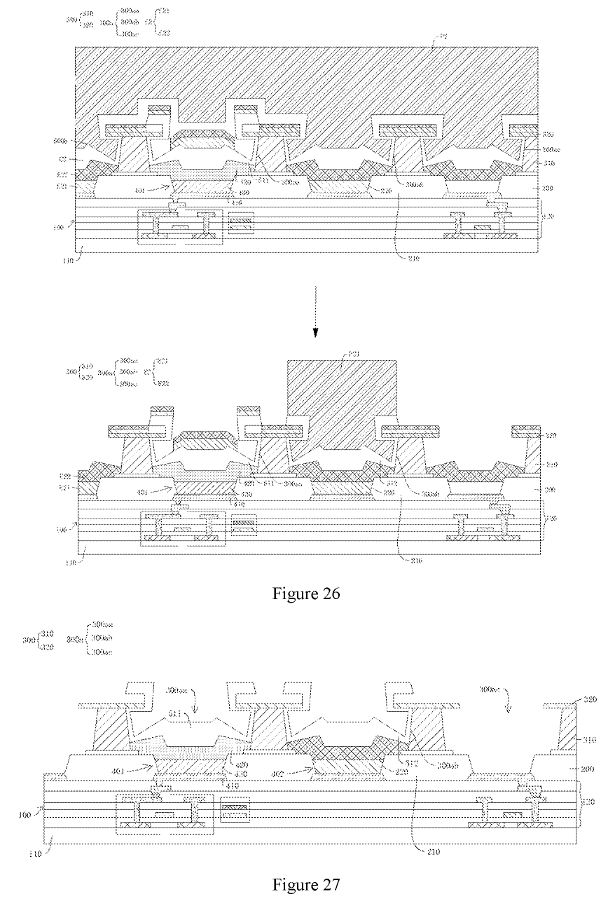

As shown in FIG. 26, at S45, at least part of the second encapsulation material layer C2 outside the second opening 300ab is removed to form a second encapsulation unit 512 disposed corresponding to the second opening 300ab.

A second protective layer P2 is fabricated on the second encapsulation material layer C2, and the second protective layer P2 is patterned to form a second protective material P21 disposed corresponding to the second opening 300ab. In addition, a second by-product P22 remains outside the second opening 300ab, and at least part of the second by-product P22 remains within the third opening 300ac.

In one embodiment, the second protective layer P2 may include a photoresist. In one embodiment, patterning the second protective layer P2 may specifically refer to patterning the second protective layer P2 outside the second opening 300ab by using exposure and development processes.

At least part of the first encapsulation material layer C2 outside the second opening 300ab is removed to form the second encapsulation unit 512 disposed corresponding to the second opening 300ab.

As shown in FIG. 27, at S46, the second conductive material layer E22 outside the second opening 300ab is removed.

At S47, the second light-emitting material layer E21 outside the second opening 300ab is removed to form a second light-emitting unit 402 disposed corresponding to the second opening 300ab.

In some embodiments, the isolation openings 300a further include the third opening 300ac, and after step S47 of forming the second light-emitting unit 402 disposed corresponding to the second opening 300ab, the fabrication method includes the following sub-steps.

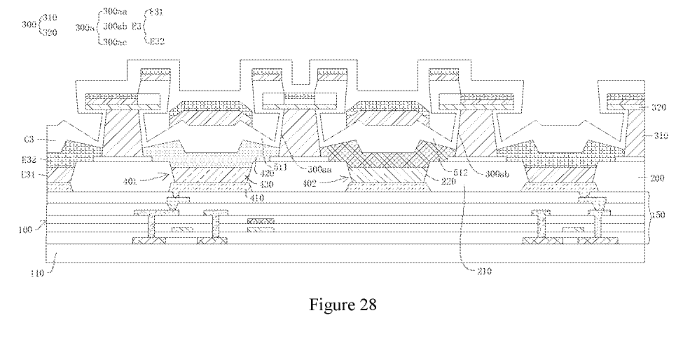

As shown in FIG. 28, at S481, a third light-emitting material layer E31, a third conductive material layer E32, and a third encapsulation material layer C3 are sequentially fabricated over the entire surface.

The third device material layer E3 may include the third light-emitting material layer E31 and the third conductive material layer E32. A third device material layer E3 may be fabricated by using an evaporation process, and the third encapsulation material layer C3 may be fabricated by using a chemical vapor deposition process.

In one embodiment, fabricating the third device material layer E3 and the third encapsulation material layer C3 over the entire surface may refer to that the third device material layer E3 and the third encapsulation material layer C3 may be located above the first encapsulation unit 511, above the second encapsulation unit 512, and within the third opening 300ac, and that the third device material layer E3 and the third encapsulation material layer C3 may be further located on the side of the isolation structure 300 facing away from the substrate 100.

In one embodiment, the third device material layer E3 may include the third light-emitting material layer E31 and the third conductive material layer E32 located on a side of the third light-emitting material layer E31 facing away from the substrate 100.

In one embodiment, due to the blocking and separation effect of the isolation structure 300, a portion of the third device material layer E3 located within the third opening 300ac may be isolated from the other portion of the third device material layer E3 outside the third opening 300ac. In one embodiment, due to the blocking and separation effect of the isolation structure 300, the third device material layer E3 cannot cover an inner wall of the isolation opening 300a in a large area and with good continuity.

In one embodiment, the third encapsulation material layer C3 may not be affected by the blocking and separation effect of the isolation structure 300, i.e., the third encapsulation material layer C3 may exhibit good continuity.

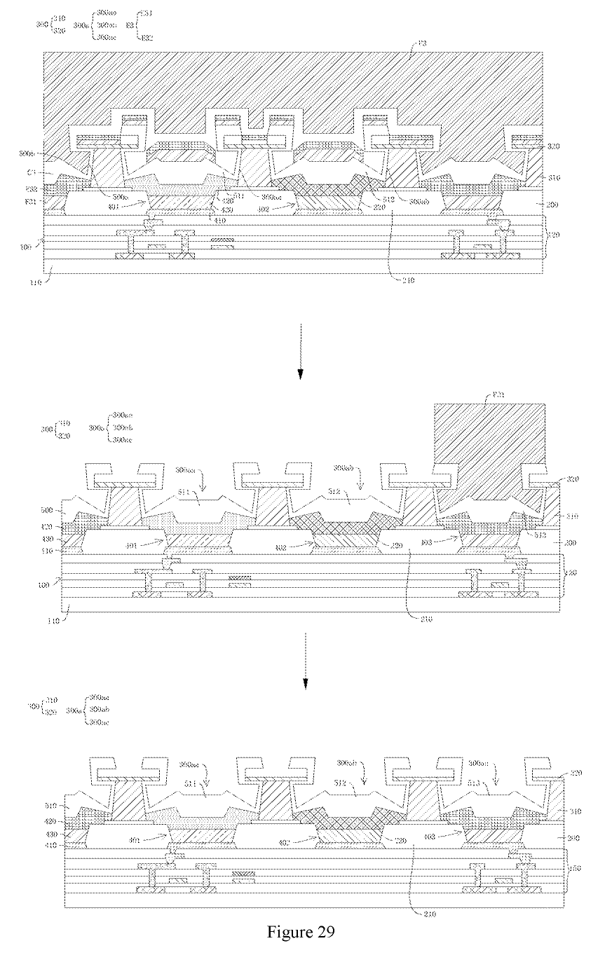

As shown in FIG. 29, at S482, at least part of the third encapsulation material layer C3 outside the third opening 300ac is removed to form a third encapsulation unit 513 disposed corresponding to the third opening 300ac.

A third protective layer P3 is fabricated on the third encapsulation material layer C3, and the third protective layer P3 is patterned to form a third protective material P31 disposed corresponding to the third opening 300ac. The third protective layer P3 may include a photoresist. In one embodiment, patterning the third protective layer P3 may specifically refer to patterning the third protective layer P3 outside the third opening 300ac by using exposure and development processes.

The third protective material P31 formed after the third protective layer P3 is patterned may be configured to protect the portion of the third device material layer E3 within the third opening 300ac, and the portion of the third device material layer E3 within the third opening 300ac is less likely to be damaged by etching in subsequent fabrication processes.

In one embodiment, a third light-emitting unit 403 disposed corresponding to the third opening 300ac may refer to that the third light-emitting unit 403 may be partially located within the third opening 300ac. In one embodiment, the third encapsulation unit 513 disposed corresponding to the third opening 300ac may refer to that the third encapsulation unit 513 may be partially located within the third opening 300ac.

At S483, the third conductive material layer E32 and the third light-emitting material layer E31 outside the third opening 300ac are removed to form the third light-emitting unit 403 disposed corresponding to the third opening 300ac.

In one embodiment, the third light-emitting unit 403 may include a first electrode 410, a light-emitting layer 430, and a second electrode 420 disposed corresponding to the third opening 300ac. The second electrode 420 may be located on a side of the first electrode 410 facing away from the substrate 100, and the light-emitting layer 430 may be located between the first electrode 410 and the second electrode 420.

In one embodiment, the first electrode 410 disposed corresponding to the third opening 300ac in the third light-emitting unit 403 may refer to a first electrode 410 located within a pixel opening 220 in communication with the third opening 300ac. In one embodiment, a portion of the structure of the light-emitting layer 430 in the third light-emitting unit 403 may be located within the third opening 300ac, and another portion of the structure of the light-emitting layer 430 in the third light-emitting unit 403 may be located within the pixel opening 220 in communication with the third opening 300ac. In one embodiment, a portion of the structure of the second electrode 420 in the third light-emitting unit 403 may be located within the third opening 300ac, and another portion of the structure of the second electrode 420 in the third light-emitting unit 403 may be located within the pixel opening 220 in communication with the third opening 300ac.

In one embodiment, the first electrode 410 of the third light-emitting unit 403 may be connected to the isolation structure 300. For example, the second electrode 420 of the third light-emitting unit 403 may be connected to a first isolation portion 310 and a conductive portion 330 of the isolation structure 300, and the second electrode 420 of the first light-emitting unit 401, the second electrode 420 of the second light-emitting unit 402, and the second electrode 420 of the third light-emitting unit 403 can be electrically connected through the isolation structure 300.

In some embodiments, after the step of removing at least part of the protective layer 600, the fabrication method further includes:
forming a second encapsulation layer 520 on a side of the first encapsulation layer 510 facing away from the base substrate 110; and
forming a third encapsulation layer 530 on a side of the second encapsulation layer 520 facing away from the base substrate 110.

The combination of the second encapsulation layer 520 and the first encapsulation layer 510 can further improve the encapsulation effect of the display panel 10.

In one embodiment, the second encapsulation layer 520 includes an organic material. Organic materials have unique flexibility and good conformability. Compared to inorganic materials, organic materials can better adapt to minor deformations that may occur in the display panel 100 in different environments, avoiding issues such as cracking due to panel bending or thermal expansion and contraction.

The combination of a plurality of encapsulation film layers, including the first encapsulation layer 510, the second encapsulation layer 520, and the third encapsulation layer 530, further improves the encapsulation effect of the display panel 10.

In one embodiment, the third encapsulation layer 530 includes an inorganic material.

The third encapsulation layer 530 may include materials such as silicon oxide, silicon nitride, or silicon oxynitride, which can provide good mechanical support and encapsulation protection to prevent the display panel 10 from being affected by the environment. Moreover, the third encapsulation layer 530 formed by the inorganic material can also effectively isolate harmful substances such as external moisture and oxygen from entering the interior of the display panel 10, thereby improving the service life and stability of the display panel 10.

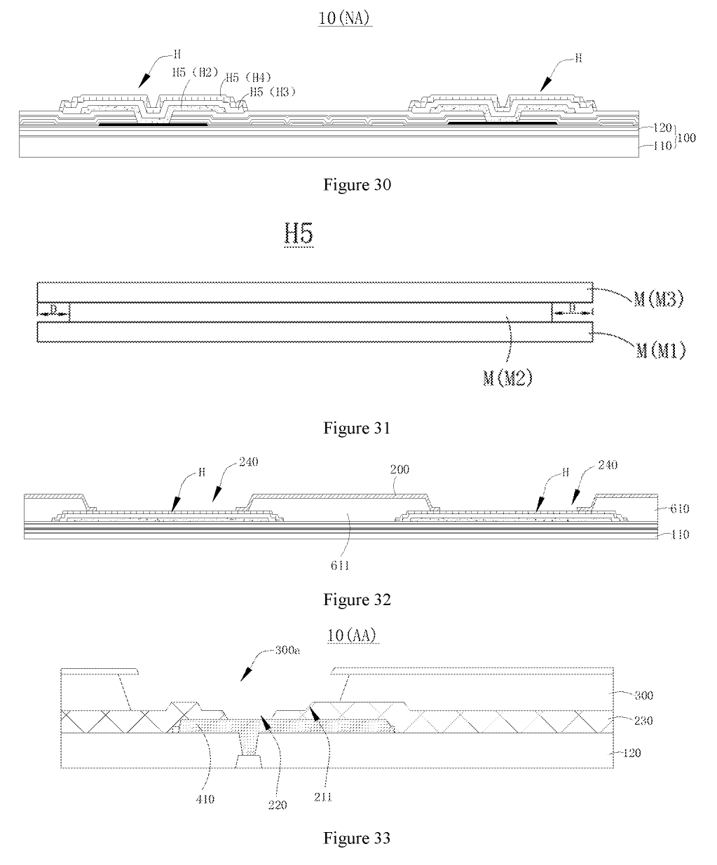

Referring to FIGS. 30 and 31, according to one embodiment of the present application which further provides a display panel 10, which is fabricated by using the fabrication method according to any one of the above embodiments. The display panel 10 includes an active area AA and a bonding area NA, and the display panel 10 further includes a base substrate 110, conductive pads H, an isolation structure 300, and a light-emitting unit 400. The conductive pads H are disposed on one side of the base substrate 110, and the conductive pads H are located in the bonding area NA. The respective conductive pad H includes at least one conductive layer H5, the conductive layer H5 includes a plurality of metal film layers M disposed sequentially in a direction away from the base substrate 110, at least two of the metal film layers M are of different materials, and edges of the metal film layers M with different materials have a spacing D in a direction parallel to the base substrate, where D satisfies: D ≤ 0.3 μm. The isolation structure 300 is disposed on one side of the base substrate 110, and the isolation structure 300 is located in the active area AA and encloses an isolation opening 300a. At least part of the light-emitting unit 400 is located in the isolation opening 300a.

The metal film layers M with different materials have different etching rates. Therefore, when the conductive layer H5 is fabricated by using an etching process, the metal film layer M with a higher etching rate in the direction parallel to the base substrate 110 may have a shorter edge compared to the metal film layer M with a lower etching rate in the direction parallel to the base substrate 110. For example, in the case where the metal film layer M with a higher etching rate is located in the topmost layer or middle layer, when the conductive layer H5 is fabricated by using the etching process, the metal film layer M with a higher etching rate has a shorter edge in the direction parallel to the base substrate 110, resulting in the spacing D between the edges of the metal film layers M with different materials in the direction parallel to the base substrate. However, when the metal film layer M with a higher etching rate is located in the bottommost layer, the metal film layer M may not be eroded by etching solutions used during the fabrication of the conductive layer H5. However, when there is no subsequent protection from the protective layer 600, etching solutions and developing solutions used during the fabrication of the light-emitting unit 400 may further erode the metal film layers M of the conductive layer, leading to a further increase in the spacing D between the edges of the metal film layers M with different materials in the direction parallel to the base substrate. In the embodiments of the present application, the protective layer 600 can protect the edges of the metal film layers M from further erosion by the developing solutions and etching solutions. Therefore, in the embodiments of the present application, the spacing D between the edges of the metal film layers M with different materials in the direction parallel to the base substrate is smaller, and D satisfies: D ≤ 0.3 μm, which improves the performance of the display panel 10.

For example, the respective conductive pad H includes three conductive layers H5: a first conductive layer H2, a second conductive layer H3, and a third conductive layer H4 disposed sequentially in a direction away from the base substrate 110. In the fabrication method for a display panel 10 according to the embodiments of the present application, the protective layer 600 is formed on one side of the base substrate 110, where the protective layer 600 covers the conductive pads H; and after the light-emitting unit 400 and the first encapsulation layer 510 are fabricated, at least part of the protective layer 600 is removed to expose at least part of the respective conductive pad H, which can prevent the developing solutions and the etching solutions from damaging the edges of the plurality of metal film layers M of the conductive pads H during the fabrication of the light-emitting unit 400 and the first encapsulation layer 510. When there is no protection from the protective layer 600, part of edges of the metal film layers M may be damaged by the developing solutions and the etching solutions, leading to a further increase in the spacing D between the edges of the metal film layers M with different materials in the direction parallel to the base substrate. In the embodiments of the present application, the protective layer 600 can protect the edges of the metal film layers M, avoiding the further increase in the spacing D between the edges of the metal film layers M with different materials in the direction parallel to the base substrate, and keeping H small, thereby improving the performance of the display panel 10.

In some embodiments, an edge of one of the metal film layers M is recessed inward in the direction parallel to the base substrate 110 relative to edges of other metal film layers M.

When the metal film layer M with a higher etching rate is located in the middle layer of the conductive layer H5, the edge of this metal film layer M is more affected by erosion than the edges of other metal film layers M with lower etching rates when the conductive layer H5 is fabricated by using the etching process. Therefore, when the conductive layer H5 is fabricated by using the etching process, the edge of this metal film layer M is recessed inward in the direction parallel to the base substrate 110 relative to the edges of other metal film layers M with lower etching rates.

In some embodiments, the plurality of metal film layers M include a first metal layer M1, a second metal layer M2, and a third metal layer M3 disposed sequentially in the direction away from the base substrate 110. An etching rate of the second metal layer M2 is greater than etching rates of the first metal layer M1 and the third metal layer M3.

For example, the first metal layer M1 is made of titanium, the second metal layer M2 is made of aluminum, and the third metal layer M3 is made of titanium. Each conductive layer H5 is fabricated by three metal film layers M. Since the second metal layer M2 is located between the first metal layer M1 and the third metal layer M3, although it has the highest etching rate by an etching solution, it is protected by the protective layer 600, which prevents a developing solutions and the etching solutions from damaging the edge of the second metal layer M2 during the fabrication of the light-emitting unit 400 and the first encapsulation layer 510. The edge of the second metal layer M2 in the uppermost conductive layer H5, i.e., the third conductive layer H4, will not be damaged by the developing solutions and the etching solutions. Therefore, the edge of the third conductive layer H4 will not be further recessed inward in the direction parallel to the base substrate 110, thereby improving the reliability of the conductive pads H.

In some embodiments, D further satisfies: D ≥ 0.05 μm. That is, after the conductive layer H5 is fabricated by using the etching process, the spacing D between the edge of the metal film layer M with a higher etching rate in the direction parallel to the base substrate 110 and the edge of the metal film layer M with a lower etching rate in the direction parallel to the base substrate 110 is greater than or equal to 0.05 μm. This ensures a material difference between at least two metal film layers M in the conductive layer H5, enhancing the performance of the conductive layer H5 and utilizing the advantages of the metal film layers M with different materials.

The conductive pads H may be configured to bond to a driver chip or a flexible printed circuit board. When the conductive pads H can bond to the driver chip, since the driver chip tends to generate heat, higher reliability is required for bonding to the driver chip. Organic materials are susceptible to high temperatures. Therefore, a portion of a planarization layer 610 that covers the bonding area NA needs to be completely removed, that is, the organic material that may affect the bonding area NA is removed, thereby improving the reliability of the bonding area NA. Certainly, to remove the portion of the planarization layer 610 that covers the bonding area NA, a portion of a pixel define layer 200 that covers the bonding area NA needs to be removed first. Therefore, after the portion of the pixel define layer 200 that covers the bonding area NA is removed, the portion of the planarization layer 610 that covers the bonding area NA is removed to fully expose the conductive pads H for bonding to the driver chip, thereby improving the reliability of the bonding area NA. Therefore, both the planarization layer 610 and the pixel define layer 200 on the conductive pads H bonded with the driver chip are removed.

As shown in FIG. 32, in some embodiments, the display panel 10 further includes the planarization layer 610 and the pixel define layer 200. The planarization layer 610 includes a planarization portion 611 located between two adjacent conductive pads H, the planarization portion 611 covers edges of the conductive pads H, the pixel define layer 200 covers the planarization portion 611, and the pixel define layer 200 is provided with bonding openings 240 exposing the conductive pads H.

Since the flexible printed circuit board generates less heat compared to the driver chip, the flexible printed circuit board does not require as high bonding reliability as the driver chip. In the embodiments of the present application, only at least part of the pixel define layer 200 that covers the conductive pads H is removed, with part of the pixel define layer 200 and the entire planarization layer 610 being retained, to expose the bonding openings 240 for bonding to the flexible printed circuit board, which can reduce process steps, thereby improving the fabrication efficiency of the display panel 10.

In some embodiments, the display panel 10 further includes the pixel define layer 200 disposed on one side of the base substrate 110. The pixel define layer 200 includes a pixel defining portion 210 and a pixel opening 220 enclosed by the pixel defining portion 210. The pixel opening 220 is in communication with the isolation opening 300a. The isolation structure 300 is disposed on a side of the pixel defining portion 210 facing away from the base substrate 110. The pixel define layer 200 can reduce crosstalk between adjacent light-emitting units 400.

As shown in FIG. 33, in one embodiment, the pixel defining portion 210 has a step 211 formed on the side facing away from the base substrate 110, and an orthographic projection of the step 211 on the base substrate 110 is within an orthographic projection of the isolation opening 300a on the base substrate 110.

A portion of material of a pixel define material layer 230 corresponding to a first electrode 410 is first etched away, to form a pixel define material portion 231, then an isolation structure material layer 330 is patterned to form the isolation structure 300 with the isolation opening 300a, and the pixel define material portion 231 is removed to form the pixel define layer 200 with the pixel opening 220. Therefore, when the pixel define material portion 231 is etched by using a mask to form the pixel opening 220, a portion of the pixel defining portion 210 outside the pixel opening 220 is also etched away, thereby forming the step 211 on the pixel defining portion 210.

According to an embodiment of the present application which further provides a display apparatus. The display apparatus includes the display panel 10 described above. Since the display apparatus according to the embodiment of the present application which includes the display panel 10 fabricated by using the fabrication method according to any one of the above embodiments, the display apparatus according to the embodiment of the present application has the beneficial effects of the display panel 10 fabricated by using the fabrication method according to any one of the above embodiments, and will not be described in detail herein.

The display apparatus in the embodiments of the present application includes, but is not limited to, devices having a display function, such as a mobile phone, a personal digital assistant (PDA), a tablet computer, an e-book reader, a television, an access control system, a smart fixed-line telephone, or a console.

The embodiments of the present application as described above neither set forth all the details, nor do they limit the present application to only the described specific embodiments. Apparently, many modifications and variations can be made in light of the above description. The embodiments are selected and described in this specification to better explain the principles and practical applications of the present application, and good use of the present application can be made and modify and use the present application. The present application is limited only by the claims and all the scopes and equivalents thereof.

What is claimed is:

1. A fabrication method for a display panel, which comprises an active area and a bonding area, the fabrication method comprising:
forming a plurality of conductive pads on one side of a base substrate, wherein the conductive pads are located in the bonding area;
forming a protective layer on one side of the base substrate, wherein the protective layer covers the conductive pads;
forming an isolation structure on a side of the protective layer facing away from the base substrate, wherein the isolation structure encloses an isolation opening;
fabricating a light-emitting unit and a first encapsulation layer, wherein at least part of the light-emitting unit is located in the isolation opening, and the first encapsulation layer is disposed on a side of the light-emitting unit facing away from the base substrate; and
removing at least part of the protective layer to expose at least part of the respective conductive pad.

2. The fabrication method according to claim 1, wherein the protective layer comprises a planarization layer and a pixel define layer, and the step of forming a protective layer on one side of the base substrate comprises:
forming the planarization layer on one side of the base substrate, wherein the planarization layer comprises a planarization portion located between two adjacent conductive pads, and the planarization portion covers edges of the conductive pads;
forming a first electrode of the light-emitting unit in the active area; and
forming the pixel define layer on a side of the planarization layer facing away from the base substrate, wherein the pixel define layer covers the planarization portion and the conductive pads.

3. The fabrication method according to claim 2, wherein the step of forming a planarization layer on one side of the base substrate comprises:
forming a planarization material layer on one side of the base substrate;
patterning a portion of the planarization material layer that corresponds to the bonding area to expose a portion of the conductive pads to form the planarization portion; and
forming a first via in a portion of the planarization material layer that corresponds to the active area, wherein the first via is configured to connect the light-emitting unit to a drive circuit.

4. The fabrication method according to claim 2, wherein the step of forming a pixel define layer on a side of the planarization layer facing away from the base substrate comprises:
forming a pixel define material layer on the side of the planarization layer facing away from the base substrate;
etching away a portion of material of the pixel define material layer that corresponds to the first electrode, to form a pixel define material portion;
fabricating an isolation structure material layer; and
patterning the isolation structure material layer to form an isolation structure with the isolation opening, and removing the pixel define material portion to form the pixel define layer with a pixel opening.

5. The fabrication method according to claim 2, wherein the planarization layer comprises an organic material, and the pixel define layer comprises an inorganic material.

6. The fabrication method according to claim 5, wherein the step of removing at least part of the protective layer comprises:
removing a portion of the pixel define layer that covers the bonding area;
removing a portion of the planarization layer that covers the bonding area to expose the conductive pads, wherein the conductive pads are configured to bond to a driver chip; and
removing a portion of the planarization layer that covers the bonding area by using an oxygen plasma ashing process.

7. The fabrication method according to claim 6, wherein the step of forming a plurality of conductive pads on one side of the base substrate comprises:
forming pad connection lines on one side of the base substrate;
fabricating an insulation layer;
forming second vias at positions of the insulation layer that correspond to the pad connection lines; and
forming the conductive pads at positions of the second vias, wherein a portion of the respective conductive pad is located within the respective second via, and another portion of the respective conductive pad is located on a side of the insulation layer facing away from the base substrate.

8. The fabrication method according to claim 5, wherein the step of removing at least part of the protective layer comprises:
removing at least part of the pixel define layer that covers the conductive pads, wherein the conductive pads are configured to bond to a flexible printed circuit board.

9. The fabrication method according to claim 1, wherein the respective conductive pad comprises a first conductive layer, a second conductive layer, and a third conductive layer disposed sequentially in a direction away from the base substrate.

10. The fabrication method according to claim 9, wherein an orthographic projection of the first conductive layer on the base substrate is within an orthographic projection of the second conductive layer on the base substrate; and
the orthographic projection of the second conductive layer on the base substrate is within an orthographic projection of the third conductive layer on the base substrate.

11. The fabrication method according to claim 1, wherein the isolation opening comprises a first opening and a second opening, and the step of fabricating a light-emitting unit and a first encapsulation layer comprises:
sequentially fabricating a first light-emitting material layer, a first conductive material layer, and a first encapsulation material layer over an entire surface;
removing at least part of the first encapsulation material layer outside the first opening to form a first encapsulation unit disposed corresponding to the first opening;
removing the first conductive material layer and the first light-emitting material layer outside the first opening to form a first light-emitting unit disposed corresponding to the first opening;
sequentially fabricating a second light-emitting material layer, a second conductive material layer, and a second encapsulation material layer over the entire surface;
removing at least part of the second encapsulation material layer outside the second opening to form a second encapsulation unit disposed corresponding to the second opening;
removing the second conductive material layer outside the second opening; and
removing the second light-emitting material layer outside the second opening to form a second light-emitting unit disposed corresponding to the second opening.

12. The fabrication method according to claim 11, wherein the isolation opening further comprises a third opening, and after the step of forming a second light-emitting unit disposed corresponding to the second opening, the fabrication method comprises:
sequentially fabricating a third light-emitting material layer, a third conductive material layer, and a third encapsulation material layer over the entire surface;
fabricating a third protective layer on the third encapsulation material layer, and patterning the third protective layer to form a third protective material disposed corresponding to the third opening;
removing at least part of the third encapsulation material layer outside the third opening to form a third encapsulation unit disposed corresponding to the third opening; and
removing the third conductive material layer and the third light-emitting material layer outside the third opening to form a third light-emitting unit disposed corresponding to the third opening.

13. The fabrication method according to claim 1, wherein after the step of removing at least part of the protective layer, the fabrication method further comprises:
forming a second encapsulation layer on a side of the first encapsulation layer facing away from the base substrate; and
forming a third encapsulation layer on a side of the second encapsulation layer facing away from the base substrate.

14. A display panel, comprising an active area and a bonding area, wherein the display panel further comprises:
a base substrate;
a plurality of conductive pads disposed on one side of the base substrate, wherein the conductive pads are located in the bonding area, and the respective conductive pad comprises at least one conductive layer, the conductive layer comprising a plurality of metal film layers disposed sequentially in a direction away from the base substrate, at least two of the metal film layers being of different materials, and edges of the metal film layers with different materials having a spacing D in a direction parallel to the base substrate, wherein D satisfies: D ≤ 0.3 μm;
an isolation structure disposed on one side of the base substrate, wherein the isolation structure encloses an isolation opening; and
a light-emitting unit, wherein at least part of the light-emitting unit is located in the isolation opening.

15. The display panel according to claim 14, wherein an edge of one of the metal film layers is recessed inward in the direction parallel to the base substrate relative to edges of other metal film layers.

16. The display panel according to claim 14, wherein the plurality of metal film layers comprise a first metal layer, a second metal layer, and a third metal layer disposed sequentially in the direction away from the base substrate, an etching rate of the second metal layer being greater than etching rates of the first metal layer and the third metal layer.

17. The display panel according to claim 14, wherein D further satisfies: D ≥ 0.05 μm.

18. The display panel according to claim 14, wherein the display panel further comprises a planarization layer and a pixel define layer, the planarization layer comprising a planarization portion located between two adjacent conductive pads, the planarization portion covering edges of the conductive pads, the pixel define layer covering the planarization portion, and the pixel define layer being provided with bonding openings exposing the conductive pads.

19. The display panel according to claim 14, wherein the display panel further comprises a pixel define layer disposed on one side of the base substrate, the pixel define layer comprising a pixel defining portion and a pixel opening enclosed by the pixel defining portion, the pixel opening being in communication with the isolation opening, and the isolation structure being disposed on a side of the pixel defining portion facing away from the base substrate; and
the pixel defining portion has a step formed on the side facing away from the base substrate, an orthographic projection of the step on the base substrate being within an orthographic projection of the isolation opening on the base substrate.

20. A display apparatus, comprising:
a display panel fabricated by using the fabrication method according to claim 1.
